(19) United States
(12) Patent Application Publication
(10) Pub. No.: US 2018/0278868 A1
(43) Pub. Date: Sep. 27, 2018

(54) Neuromorphic Digital Focal Plane Array

(71) Applicant: The Charles Stark Draper Laboratory, Inc., Cambridge, MA (US)

(72) Inventors: Robin Mark Adrian Dawson, Watertown, MA (US); Geremy Freifeld, Cambridge, MA (US); Dorothy Carol Poppe, Cambridge, MA (US); Eric Hoke, Cambridge, MA (US); Brent Hollosi, Cambridge, MA (US); Richard Morrison, Cambridge, MA (US); Richard Wood, Cambridge, MA (US); Steven J. Byrnes, Watertown, MA (US); Benjamin F. Lane, Sherborn, MA (US)

(21) Appl. No.: 15/927,532

(22) Filed: Mar. 21, 2018

Related U.S. Application Data
(60) Provisional application No. 62/474,388, filed on Mar. 21, 2017.

(51) Int. Cl. H04N 5/369; H01L 27/146; H01L 31/107; H01L 31/18; H01L 25/16; H04N 5/33; H04N 5/232; G06N 3/063; G06N 3/04

(52) U.S. Cl. CPC H04N 5/369; H01L 27/14634; H01L 31/107; H01L 31/18; H01L 25/167; G06N 3/04; H01L 27/14652; H04N 5/332; H04N 5/23229; G06N 3/063; H01L 27/14636

(57) ABSTRACT

This invention discloses a multispectral imaging system, DFPA (digital focal plane array), in the form of an integrated circuit of three structures each of which is implemented on a chip. The top structure consists of detectors capable of imaging in the visible to LWIR wavelengths. The middle structure of neuromorphic focal array contains ROI circuitry and inherent computing capabilities for digitization, convolution, background suppression, thresholding, and centroid determination of the ROIs. The bottom structure (dubbed common digital layer) is capable of additional image processing tasks and reconfiguring the neuromorphic focal array. In a simpler embodiment of the invention, the system only has the top two layers, with an external processor taking over the role of the common digital layer.

### RELATED APPLICATIONS

This application claims the benefit under 35 USC 119(e) of U.S. Provisional Application No. 62/474,388, filed on Mar. 21, 2017, which is incorporated herein by reference in its entirety.

### BACKGROUND OF THE INVENTION

Typically, a focal plane array is a sensor with a 2-D array of pixels on the focal plane (also called the image plane). In an analog camera, the focal plane is the film behind the lens, whereas in a digital camera, the focal plane is a planar light detector array of picture elements or pixels with a readout circuit replacing the traditional film. The detected light signal is digitized into certain number of bits n, e.g., n=8, for representing 2ⁿ=256 intensity levels. In the numerical example just cited, a single gray-level image of 1024×1024 pixels would be of size 1024×1024×8 bits=8 Megabytes (Mb), where 1 byte=8 bits. For a color image with RGB detection, the image size would be 3×8=24 Mb.

Typically, real-time image processing involves not just a single image but a stream of images, where each image has a time stamp. Furthermore, the detected light may be composed of many bands. A typical multispectral image may consist of several infrared (IR) bands in addition to the visible or red/green/blue (RGB) bands. In addition, the recorded intensity levels of a band may require more than the 8 bits cited above. Thus, for many practical applications the size of the “image cube” (image data or, simply, image) may be several Gigabytes (Gb).

Traditionally, the functionality of the focal plane array is limited to recording and outputting the image data, which are the digitized pixel values of the focal plane array. The image data is transferred to external processors (computers) for analysis. Thus, the size of the image data and its processing are often limiting factors in real-time image processing and data acquisition.

### SUMMARY OF THE INVENTION

The present invention concerns a new neuromorphic digital focal plane array that cannot only register the image intensities but can also perform a great deal of additional processing, in a way comparable to neurons of the human brain. Thus, it can speed up both image processing and image acquisition.

Using the human eye as analogy, if the focal plane arrays can be enhanced with just a fraction of the capabilities of the neurons of the human brain, it would go a long way to achieve real-time vision processing. Neuromorphic focal plane arrays are designed to achieve some of the capabilities of sensors/neurons in the human eye.

The main limitation of the traditional focal array processing methods is that the amount of data generated by the focal plane is very large and all of it must be transported to a processor to carry out the analysis of the data. This requires considerable computing power and creates the need for extremely high speed data channels. Moreover, for analysis of reconnaissance data from a satellite or a plane, for example, the data channels have to be wireless, which further slows down image analysis. Moreover, the processing of all of this data requires power.

In this invention, neuromorphic and digital functions are incorporated into a digital focal plane array to provide initial processing of the incoming light information. This can be used to reduce the load on the computer processing later in the image processing pipeline. For example, the disclosed system could provide centroid information to the system or saliency information. This moves the image analysis closer to the location where the light is captured, speeding up the analysis, reducing the power requirements and enabling real-time feedback functions that are not possible with the former methods.

In implementations, the system can be fully integrated in a stack of several structures. The top structure or chip is a photo sensitive array that can be made of a number of different materials depending on the wavelengths of interest. For example, InGaAs could be used for short wave infrared sensitivity or a strained layer super-lattice material for long wave infrared sensitivity. CMOS (complementary metal oxide semiconductor) devices and CCDs (charge coupled device) could be used for wavelengths in and near visible wavelengths. The middle structure or chip has a neuromorphic architecture that digitizes photo current. The middle structure's neuromorphic architecture has a focal plane array, connected with a common interface to multispectral detector arrays, corresponding to separate tracking regions of interest (ROIs), for example, of the top structure. The bottom structure or chip is a digital circuit that provides counters, shift registers and other functionality that enables determination of the light intensity, subtraction of background signal and other functions.

The disclosed system performs significant signal processing directly at or near the focal plane, and prior to the digital circuits, to provide rapid extraction of information, thus delivering higher level analysis of the image data than simple photon counts. This dramatically reduces power consumption and enables faster information processing. Specifically, this enables real-time operation of the COSS (celestial object sighting system) platform, in one specific example.

Combining the detector arrays in the top structure, neuromorphic layer in the middle structure and the digital layer in the bottom structure of the system yields functionality for a number of different civilian, industrial, scientific, and military applications.

In general, the system features a neuromorphic digital focal plane array imaging system and method with potentially three structures, for acquisition and on-focal plane array analysis of multispectral and multi-region data. The top structure acquires data in the form of photo current which is passed to the neuromorphic focal array of the middle structure through synapses of sensing elements (pixels). The middle structure digitizes photo current into pixel intensities, and performs basic image processing tasks such as convolution to enhance SNR. The optional bottom structure performs pixel shift integration, and after background subtraction only those pixels above a threshold are selected for further processing. Further processing includes connected component analysis and centroid determination. The bottom structure may also include additional signal processing, logic configuration control and circuits for routing data to periphery.

In general, according to one aspect, the invention features a focal plane array system comprising a detector array in a top structure, a neuromorphic layer in the middle structure, and a digital layer in the bottom structure.

In the preferred embodiment, the system comprises a stack of three individual chips each containing one of the top structure, middle structure, and bottom structure. Typically, the top structure comprises one or more detector arrays sensitive in any wavelength region from visible to long wavelength infrared. In one case, the detector array of the top structure includes avalanche photodiodes.

The middle layer is a neuromorphic focal plane array including interconnected neurons. These are used to form region of interest circuits capable of digitization, convolution, background suppression, thresholding and/or centroid determination of the regions of interest.

If included, the bottom structure layer is capable of additional image processing steps including reconfiguration of region of interest circuits of the middle structure and sending image data above a threshold to a host computer system.

In specific examples, variable trigger and quenching parameters applied by the middle layer are adjusted by the bottom layer. Also, separate tracking regions of interest (ROIs) can be specified by the bottom layer and pixels are shifted in the middle layer to stabilize multiple objects moving in different directions relative to the system.

In general, according to another aspect, the invention features a system that comprises only a detector array in a top structure and a neuromorphic layer in the middle structure.

In general, according to another aspect, the invention features a method of fabricating a focal plane array system. The method comprises attaching an interposer to neuromorphic structure and attaching an image sensor to the interposer.

For example, the interposer can be silicon and might have conductive contacts and vias that provide conducting paths through the interposer. The image sensor might then be attached via ball contacts to the interposer. Finally, the digital structure can be attached to the middle structure.

In general, according to another aspect, the invention features method of fabricating a focal plan array system, comprising thinning a neuromorphic structure and attaching an image sensor to the thinned neuromorphic structure.

The above and other features of the invention including various novel details of construction and combinations of parts, and other advantages, will now be more particularly described with reference to the accompanying drawings and pointed out in the claims. It will be understood that the particular method and system embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a system level schematic diagram of the DFPA (digital focal plane array) of the present invention.

FIG. 2A is a schematic representation of an individual neuron of the middle structure.

FIG. 2B is a schematic representation of the convolution capability inherent in the neuromorphic focal array of the middle structure.

FIG. 3 shows the image processing flow of existing COSS platform using conventional focal plane array.

FIG. 4 shows the process flow of the DFPA of the present invention.

FIGS. 5A-5C are schematic side plan views showing a preferred method for manufacturing DFPA.

FIGS. 6A-6F are schematic side plan views showing an alternate method for manufacturing DFPA.

FIGS. 7A-7B are schematic side plan views showing a variation for a portion of the method illustrated in FIGS. 6A-6F.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In general, embodiments of the present invention encompass multi-functional active and passive imaging neuromorphic Digital Focal Plane Arrays (DFPA) that are preferably reconfigurable. They can also employ adaptive algorithms that optimize the operation of the reconfigurable sensors in real-time to enhance the data collection for the end use imaging application.

In operation, the system might be used for multiple, separate tracking regions-of-interest (ROIs) specified at the system level to enhance the signal to noise ratio for moving targets from moving or stationary platform. The top structures can include ultraviolet (UV), visible (VIS), near IR (NIR), shortwave infrared (SWIR), medium wave infrared (MWIR), and/or long wave infrared (LWIR) pixel arrays. Thus, in one example, it might be used to enable object identification during the day and tracking at night.

The system can provide reduced data load for sparse data applications such as tracking or object sighting against atmospheric or other large backgrounds.

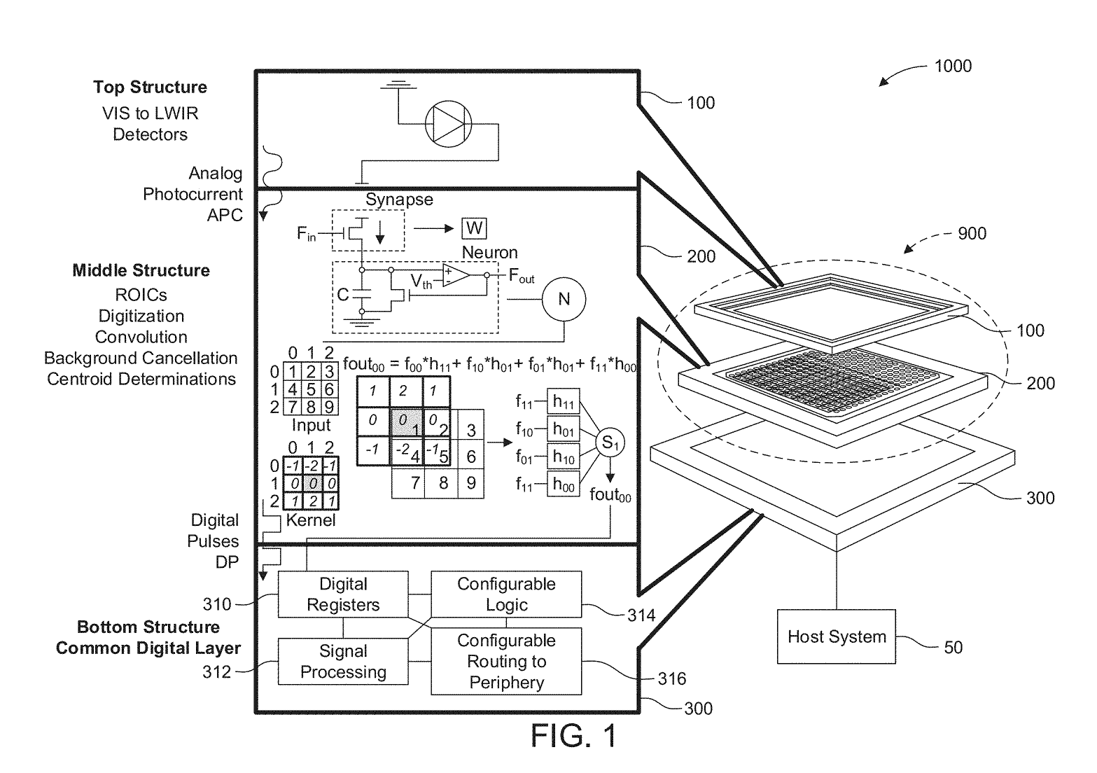

FIG. 1 is a schematic diagram of the complete neuromorphic DFPA imaging system 1000, which has three stacked structures. The three structures are: top structure 100 which includes the sensor, middle structure 200 which includes the neuromorphic focal plane array and the bottom structure 300 which includes the common digital layer (CDL).

The top structure 100 is an array of photodetectors or detection pixels. In examples, the photodetectors are capable of sensing in the ultraviolet to visible (UV-VIS) and to LWIR range of the electromagnetic spectrum, although other spectral bands or narrower bands are possible. The detectors can be APDs (Avalanche Photo Diodes) also.

The middle structure 200 of the system implements a neuromorphic architecture. It includes arrays of interconnected elements, each of which inherently holds its own computing ‘instructions’ and ‘memory’ to mimic many functions of the brain (see Russell, Mihalas, von der Heydt, Neibur and Etienne-Cummings, “A model of proto-object based saliency”, Vision Research, 94, 2013). These elements work together, in parallel, asynchronously, to transform sensor data into information. Communication between elements is in the form of rate-encoded spikes. Middle structure converts analog photo current (APC) into digital pulses (DP).

In one implementation, the middle structure 200 provides a reconfigurable analog interface between the top structure 100 photodetectors and the bottom digital structure 300. The neuromorphic focal plane array of the middle structure is connected with a common interface to multispectral detector arrays, corresponding to separate tracking regions (ROIs), of the top structure 100. In one implementation, the middle structure 200 includes Region of Interest Circuits (ROICs) that process different groups of pixels of the top structure 100. The middle structure 200 typically also performs convolution for signal to noise ratio (SNR) enhancement.

The fast data flow and processing connection between the top and middle structures lends to sparse data processing for subsequent image processing tasks. For example, convolution, background subtraction and thresholding in the middle structure 200 can lead to less pixel data that needs to be exported for subsequent image processing tasks.

The middle structure functionalities are grouped as Tier 2 activities.

The bottom structure 300, connected to a host computer system 50, includes more advanced image processing functions, typically grouped as Tier 1 interconnected functions such as digital registers 310, signal processors 312, configurable logic control 314 and configurable routing periphery 316.

The bottom structure is also called the Common Digital Layer (CDL) and may be treated as an optional layer, in which case its functions will be carried out on an external processor. The two-structure system without the optional CDL is designated 900.

Neuromorphic Focal Array Architecture:

The basic elements of the focal array of the middle structure 200 are interconnected neurons. Examples of possible neuron models are described in the U.S. Provisional Appl. No. 62/474,353, filed on Mar. 21, 2017, entitled “Neural Architectures and Systems and Methods of Their Translation”, by Wood et al., and subsequent U.S. patent application Ser. No. 15/927,347, by Wood et al., filed on Mar. 21, 2018. They describe neuromorphic elements such as neurons and synapses and methods for implementing algorithms. The teachings of these applications are incorporated herein by this reference in their entirety.

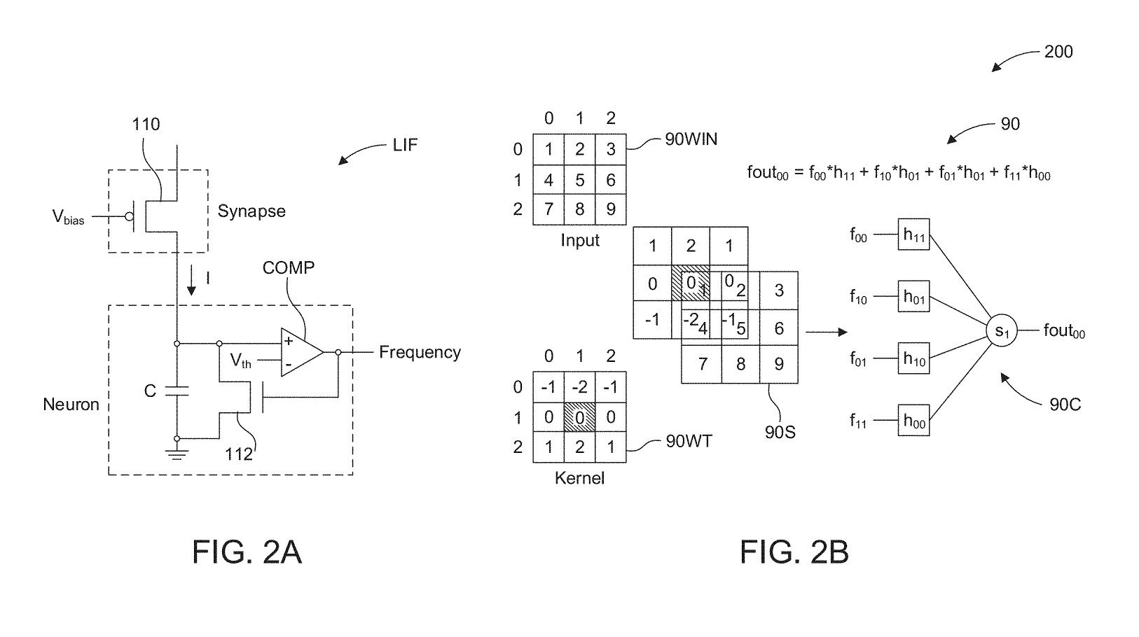

Examples of the elements of the middle structure 200 are shown in more detail in FIG. 2A and FIG. 2B.

Generally, in one example, a linear integrate-and-fire (LIF) neuron model (FIG. 2A) is employed that comprises of a synapse and neuron. The synapse is comprised of a FET (Field Effect Transistor) 110 or series of FETs; FET 110 serves to adjust current flow by adjusting V_{bias}. The neuron is comprised of an integrating capacitor C, comparator COMP, and reset FET 112. Basic operation involves charging the capacitor C through the synapse. Once the capacitor's top plate reaches a threshold voltage, the comparator COMP fires. This event can be used to propagate information and reset the capacitor voltage allowing subsequent integrate-and-fire cycles to occur. On one embodiment, each pixel photodetector in the top structure 100 has its own associated LIF circuit as shown in FIG. 2A and with each photodetector charging a capacitor C through its synapse.

This LIF node is capable of several types of data processing and transformations depending on the synapse's gate and source stimulus and the comparator's configuration. Furthermore, the synapse enables weighting of the integrated charge through numerous methods, e.g., FET width scaling, multiple synaptic paths, and adaptable gate voltage bias via wired control or a programmable floating-gate. This can be used to perform scalar or non-linear functions allowing for features like per-neuron gain control or more complex mathematical operations like logarithmic transformations.

For a sensor or photodetector of the top structure 100 that provides electrical current information, the charge from the photodetector is integrated onto the capacitor C and the comparator COMP produces a fixed-width pulse when the capacitor voltage reaches the threshold. In this way, the comparator produces fixed-width pulses at a rate proportional to the supplied current making the output a frequency-coded representation of the sensor/photodetector current. Sensor current is scaled from 0 to 1 based on the drain current of the synapse which is controlled by V_{bias}, which may be an analog value or a frequency/time coded signal.

LIF characteristics and features are summarized in the following table:

| LIF node enabling characteristics | Benefits for sensor systems |
|---|---|
| Ability to process voltage, current, | Low power data conversion between |
| frequency, or time information. | sensors and the digital layer (the |
| Output the signal in the frequency | third structure of FIG. 1). |
| or time domains. | |
| Direct interfaces with digital logic | |
| or subsequent LIF stages enabling | |
| further quantization or | |
| computation, respectively. | |
| The input can be scaled via | Reconfigurable synaptic modulation |
| synapse modulation. | for real-time scaling changes. |
| Input to output relationships can | |
| be linear or non-linear depending | |
| on the configuration. | |
| Multiple sensor inputs can be | Multi-modal processing of multiple |
| provided through separate synapses | sensor streams at the same time. |
| to a single neuron. | |

The middle structure 200 of the DFPA 1000 is also capable of some basic image processing steps. An example is the convolution step 90 as shown in FIG. 2B. Here the convolution is a 3×3 weighted average of a 3×3 image window 90WIN. Depending on the choice of weights 90WT, convolution can serve to enhance SNR (low pass filter), find edges (high pass filter), or other features. The convolution is implemented by sliding the convolution window with weights 90W across the image that is produced by the array of photodetectors as shown in 90S. Each image pixel value is replaced by the average. 90C is a simplified circuit representation of convolution.

Digitizing pixel values (including gain and other unary transformations) and convolution are operations performed in the middle structure.

The basic element of FIG. 2A can be modified and combined with other synapses to build more complex functions and carry out mathematical transformations. Specifically, techniques include the adjustment of the trigger sensitivity so it can be tailored to different detector types without redesigning. However, the actual counting of the pulses and other functions that become available in the digital domain cannot be implemented using this architecture alone. However, combining the neuromorphic approach with the bottom structure 300 (digital tier) as described by Schultz, Kelly, Baker, Blackwell, Brown, Colonero, David, Tyrrell and Wey, “Digital-Pixel Focal Plane Array Technology,” Lincoln Laboratory Journal, 20, 2014, p. 36, provides a set of extremely powerful capabilities that can be mixed and matched on the fly to optimize the functionality for different applications.

The specific functionalities provide by the DFPA 1000 include:

1. Variable trigger and quenching parameters applied by the middle structure 200 are be adjusted at the request of the digital structure 300 to reconfigure the performance depending on the detector type: SWIR, MWIR, LWIR, VIS or avalanche photo diode (APD) of the top structure 100. Thus, a single design in terms of the middle structure 200 and the digital or bottom structure 300 can be used for multiple detector types, specifically, detectors in bands with fundamentally difference background signal levels that are employed in the top structure 100. It also allows for switching between passive and linear APD modes on the fly, allowing the DFPA 1000 to support passive and active modes of operation based on commands at the system level.

2. Separate tracking regions of interest (ROIs) specified at the system level by the host computer system 50 where pixels are shifted to individually stabilize multiple objects moving in different directions relative to the system. Data from inertial sensors and/or accelerometers and prior information on the trajectories of the moving objects can be used by the DFPA 1000 to specify the ROIs and pixel shifts, greatly improving the signal to noise ratio and accuracy of object position detection. This enables use of a smaller optical system as the integration time can be tailored to the object being observed. Longer integration times mean that smaller optical apertures can be used, dramatically reducing the overall size and weight of the system.

3. Extremely low power detection and initial processing of sensor information to dramatically reduce the data load for sparse data applications such as target tracking or observing objects against the atmospheric or other large background signals.

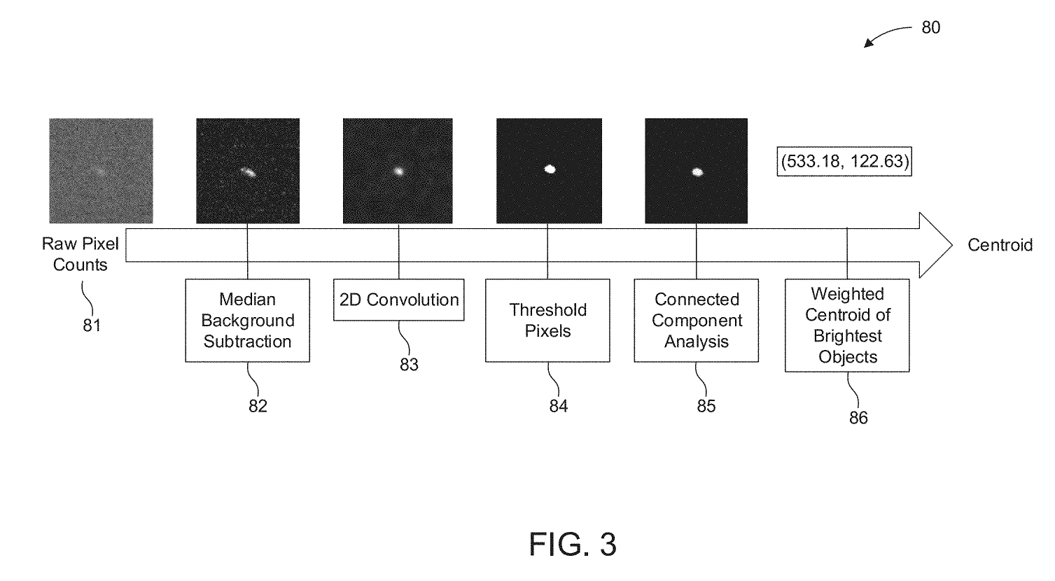

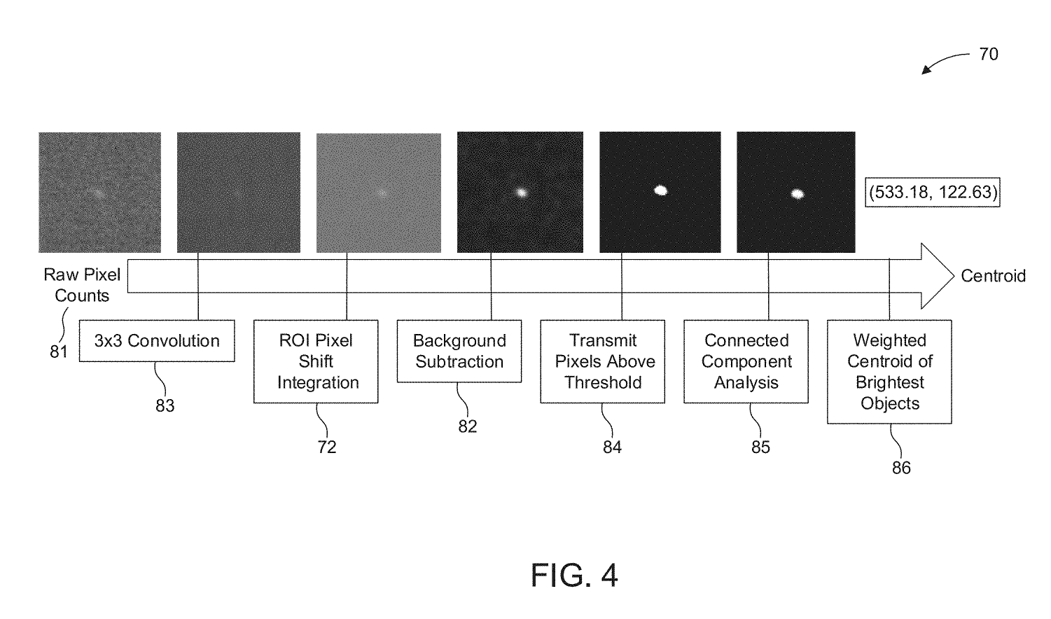

The advantages of neuromorphic middle structure 200 combined with the digital bottom structure 300 are illustrated by comparing present COSS image process flow algorithm with traditional focal arrays (FIG. 3) to plan using the inventive DFPA (FIG. 4).

Combining the neuromorphic approach with the digital structure digital tier approach can enable the transfer of data of only those pixels that contain features of interest, such as targets, objects of interest and objects used for reference, by taking advantage of the frequency to intensity feature of the digital focal plane. This saves the digitization and transfer of pixels that contain no signal of interest, dramatically reducing system power consumption and enabling increased frame rate. Typical sensors digitize all of the pixels in the array at a cost of about 5 nano J/pixel conversion. The power associated with just the digitization of 160 Mpixels is 24 Watts which would be dissipated directly on the sensor. Downstream processing of all these pixels boosts the power levels by almost two orders of magnitude such that some systems can draw almost 2 kilowatts (FIG. 3). Extracting only the centroids of interest using the process flow 80 in FIG. 3 such that only hundreds or a few thousand objects are processed will reduce the power dissipation by two orders of magnitude.

The steps involved in the extraction of centroids are to start with raw pixel counts 81, followed by median background subtraction 82, convolution 83, thresholding 84, connected common analysis 85, and weighted centroid computation 86.

FIG. 4 shows a process flow 70 for image processing using the DFPA 1000 for COSS, for example. The existing flow 80 (FIG. 3) requires that all the pixels be digitized at greater than 20 frames/sec and passed to the system computer for processing. The system processor then crunches all the image data to find the small number of centroids that are required for the navigation. Flow 70 enabled by the DFPA (FIG. 4) allows for extraction of salient features so only the pixels containing star and satellite information are transferred to the host computer system 50. The flow includes a 3×3 convolution 83, made possible by the neuromorphic middle structure 200, and indicated steps in Tier 1 that reduce the data to only the pixels with star and satellite information. This reduces the data rate out of the DFPA 1000 to host computer system 50 by 3-4 orders of magnitude from tens of gigabits per second to megabits per second. If functionality in Tier 1 hardware can support on-chip implementation of connected component analysis and weighted centroiding, a further data reduction to hundreds of kilobits per second can be achieved.

One main difference between FIGS. 3 and 4 is that convolution 83 in FIG. 4 is performed as a Tier 2 operation in the middle structure 200 (FIG. 1) by the DFPA itself, whereas in FIG. 3 it is performed at an external processor after the data is captured. In FIG. 4 it is performed immediately after raw pixel counts 81. The focal array assembly can also perform ROI pixel shift integration 72, not present in FIG. 3, within the neuromorphic array, followed by the Tier 1 functions of background subtraction 82, transmission of pixels above threshold 84, connected component analysis 85, and centroid computation 86 within the DFPA circuitry combined with digital structure. In contrast to FIG. 4, all the processing after digital capture of pixel intensities are performed external to focal plane array assembly in FIG. 3.

Fabrication:

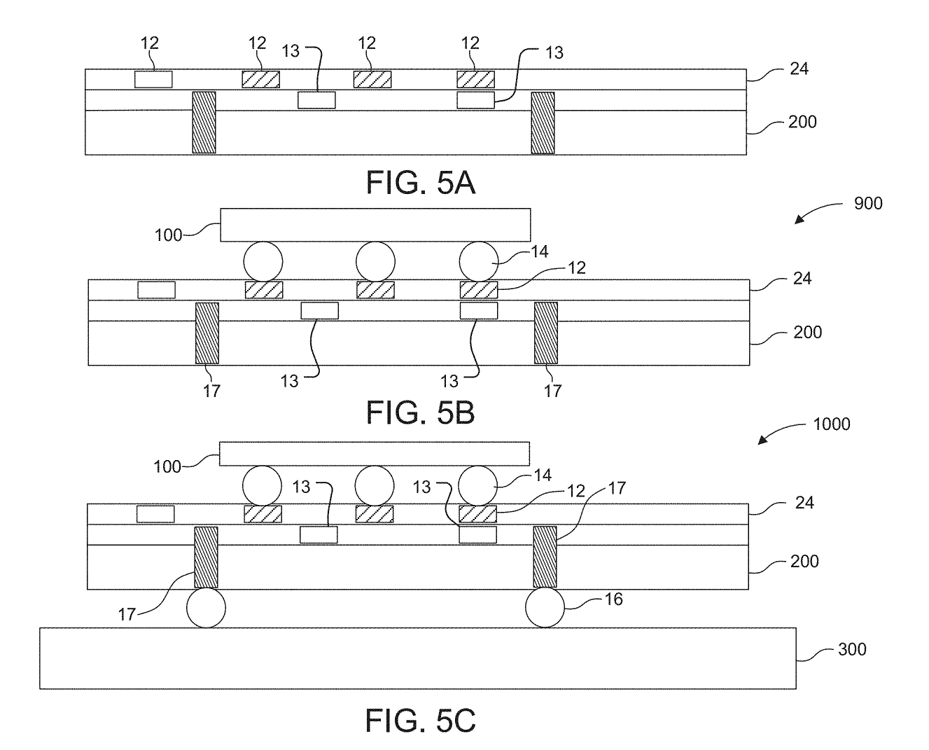

FIGS. 5A-5C show steps for one method for fabricating the system 1000.

First, a silicon interposer 24 is attached to the middle (neuromorphic) structure 200 as shown in FIG. 5A. The interposer 24 contains copper conductive contacts 12 for vias that provide conducting paths through the interposer 24. These contacts match the output 13 of the pixels of the pixel processing pipelines in the middle structure 200.

Then, the top structure (image sensor) 100 is attached via ball contacts 14 to copper conductive contacts 12 of the interposer 24 as shown in FIG. 5B.

Finally, the bottom (digital) structure is attached via a ball array 16 to the middle structure 200 as shown in FIG. 5C to the output channels 17 of the middle structure. FIG. 5C now is the complete system 1000 as shown in FIG. 1.

The bottom structure (CDL) can optionally be left out of the system, if desired. The embodiment described in FIGS. 5A-5C is especially well suited for omitting the CDL. FIGS. 5A and 5B constitute an embodiment of the optional system 900 as shown in FIG. 1.

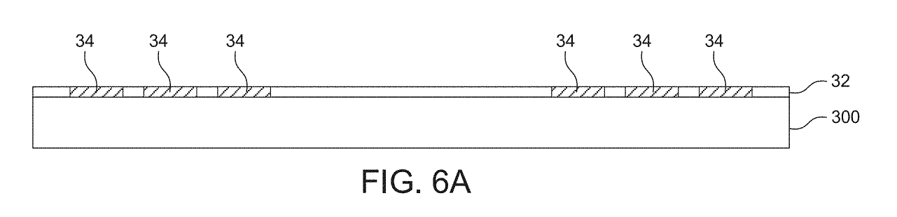

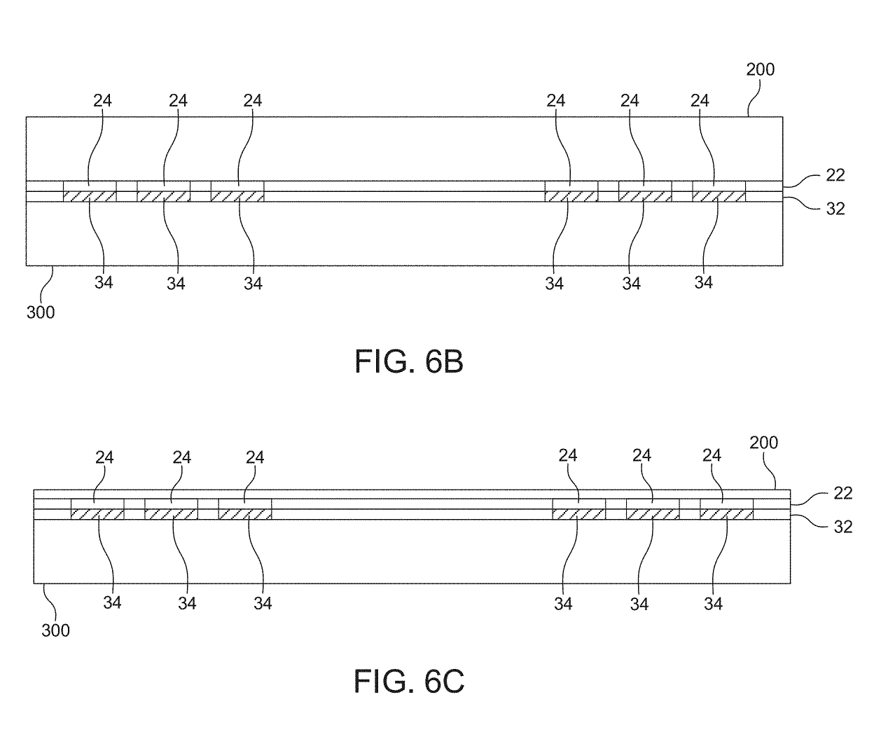

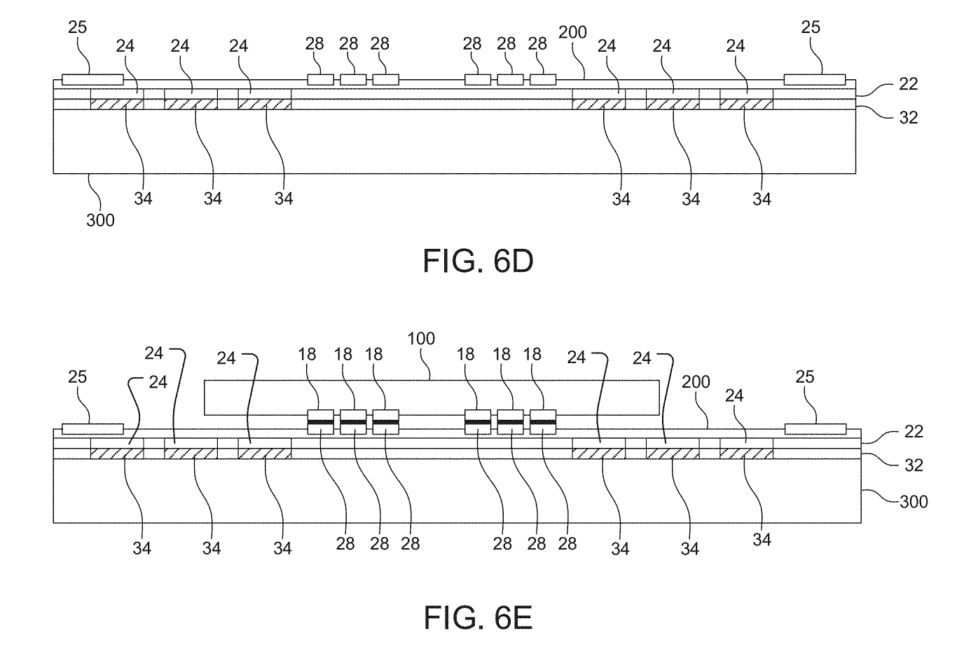

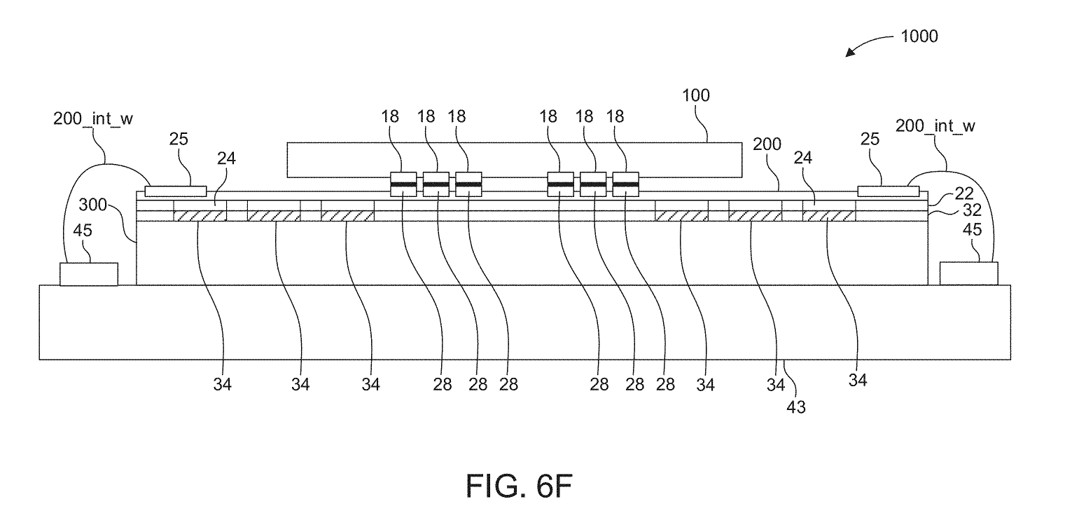

FIGS. 6A through 6F show steps for another method of fabrication of the system 1000.

FIG. 6A shows the bottom structure 300, here also referred to as the common digital wafer. Copper pads 34 are formed in a chemical vapor deposition (CVD) layer 32. In one example, this is achieved by the use of chemical mechanical polishing (CMP) to expose the copper pads in the CVD layer. These copper pads are designed to line up with the pads of the middle structure 200.

FIG. 6B shows the middle structure 200 bonded to the bottom structure 300. Specifically, the copper pads 24 of the middle structure 200 line up with the copper pads 34 of the bottom structure 300. In one example, a direct bond interconnect (DBI) between the bottom structure and the middle structure is used. Both wafers have CVD layers (22 for middle structure and 32 for bottom structure) that covers wafer surfaces. The copper pads are engineered to form a robust chemical bond during the direct bond interconnect process.

FIG. 6C shows result of the next step. The middle structure 200 is ground and thinned using CMP. Currently, this wafer is thinned to approximately 10 μm thick.

In FIG. 6D, a CVD oxide is deposited (not shown) on the exposed middle structure wafer 200. Photolithography and reactive ion etching (RIE) are then used to open vias in the sensor area to the circuits using the circuit layout of the middle structure. The vias must meet ball solder ball pitch of the top structure/sensor 100 or the wire bond pitch of the top sensor 100. Then, aluminum (Al) or copper (cu) pads 28 are deposited on the vias for a sensor attach and wire bond attach (25 on left and right are wire bond pads).

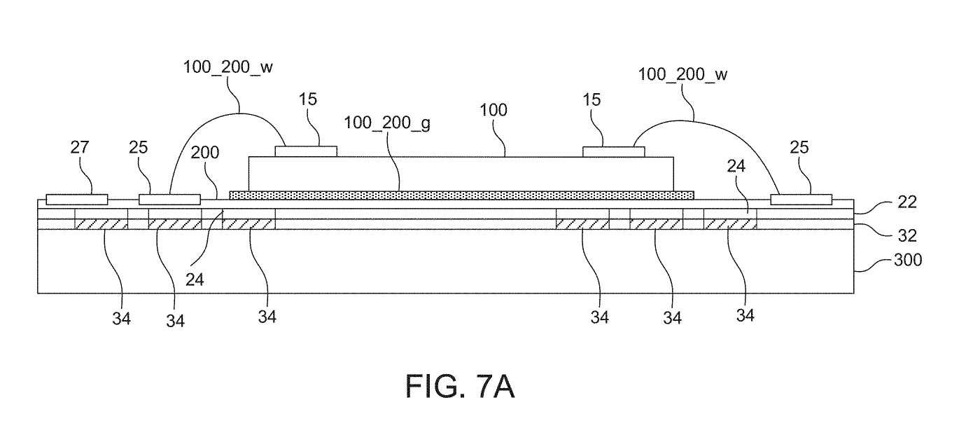

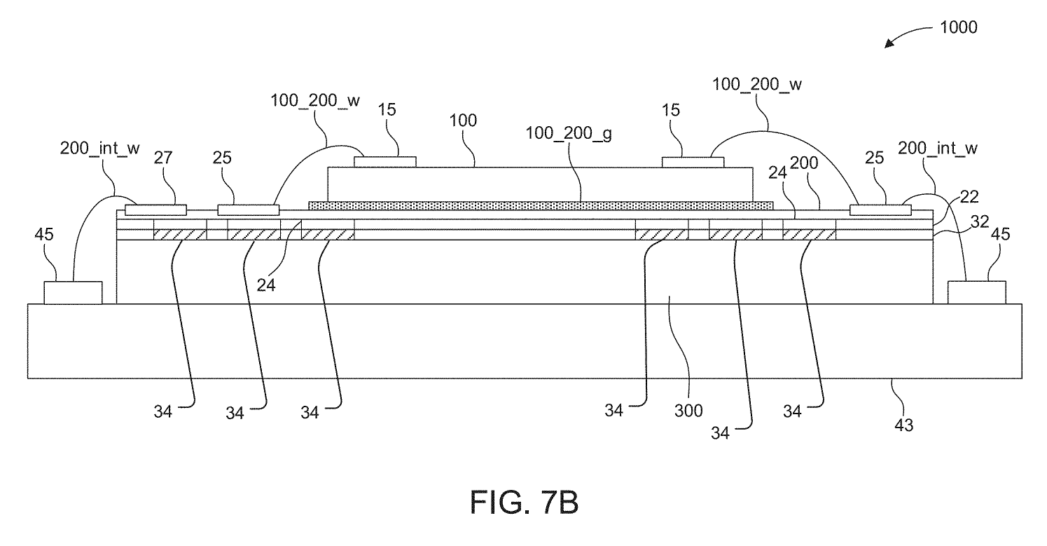

FIG. 6E shows the attachment of the top structure/sensor to the middle structure 200 via the aluminum or copper pads 28 on the middle structure. Specifically, the top structure is flip chip bonded onto Indium bumps 18. If flip chip bonding is not possible, then wire bond pads should be used (FIGS. 7A and 7B).

FIG. 6F shows the final structure 1000 with interposer. The interposer 43 wire bond pads 45 are wire bonded 200_int_w (on left and right) to the middle structure wire bond pads 25. In one example, the interposer 43 is then directly mounted onto the system circuit board that also has the host computer system 50.

FIGS. 7A and 7B illustrate alternate embodiments of 6E and 6 F. Here the top structure wire bond pads 15 are formed on the top structure 100 which are then wire bonded 100_200_w to middle structure 200 wire bond pads 25. In this example, the top structure can be simply glued (100_200_g) onto the middle structure. This is most appropriate where flip chip bonding cannot be utilized.

FIG. 7B illustrates the final system with the bottom structure mounted on the interposer using wire bond 200_int_w using bond pads 45 on the interposer 43 and 27 on the middle structure 200.

While this invention has been particularly shown and described with references to preferred embodiments thereof, it will be understood by those skilled in the art that various changes in form and details may be made therein without departing from the scope of the invention encompassed by the appended claims.

What is claimed is:

1. A focal plane array system comprising:
a detector array in a top structure;
a neuromorphic layer in the middle structure; and
a digital layer in the bottom structure.

2. A system as in claim 1, wherein the system comprises a stack of three individual chips each containing one of the top structure, middle structure, and bottom structure.

3. A system as in claim 1 wherein the top structure comprises one or more detector arrays sensitive in any wavelength region from visible to long wavelength infrared.

4. A system as in claim 1 wherein the detector array of the top structure includes avalanche photodiodes.

5. A system as in claim 1 wherein the middle layer is a neuromorphic focal plane array including interconnected neurons.

6. A system as in claim 1 wherein the neuromorphic layer of the middle structure includes region of interest circuits capable of digitization, convolution, background suppression, thresholding and/or centroid determination of the regions of interest.

7. A system as in claim 1, wherein the bottom structure is capable of additional image processing steps including reconfiguration of region of interest circuits of the middle structure and sending image data above a threshold to a host computer system.

8. A system as in claim 1, wherein variable trigger and quenching parameters applied by the middle structure are adjusted by the bottom structure.

9. A system as in claim 1, wherein separate tracking regions of interest (ROIs) are specified by the bottom structure and pixels are shifted in the middle structure to stabilize multiple objects moving in different directions relative to the system.

10. A system comprising:
a detector array in a top structure; and
a neuromorphic layer in the middle structure.

11. A method of fabricating a focal plane array system, comprising:
attaching an interposer to neuromorphic structure;
attaching an image sensor to the interposer.

12. A method as claimed in claim 11, wherein the interposer is silicon.

13. A method as claimed in claim 11, wherein the interposer has conductive contacts and vias that provide conducting paths through the interposer.

14. A method as claimed in claim 11, wherein the image sensor is attached via ball contacts to the interposer.

15. A method as claimed in claim 11, further comprising attaching a digital structure to the middle structure.

16. A method of fabricating a focal plan array system, comprising:
thinning a neuromorphic structure;
attaching an image sensor to the thinned neuromorphic structure.

17. A method as claimed in claim 16, further comprising attaching a digital bottom structure to the neuromorphic structure.

18. A method as claimed in claim 16, further comprising depositing pads on the neuromorphic structure and/or the digital bottom structure.

19. A method as claimed in claim 16, further comprising attaching a digital bottom structure to the neuromorphic structure using a direct bond interconnect process.

20. A method as claimed in claim 16, further comprising connecting the digital bottom structure to a circuit board using an interposer.
